(19) United States
(12) Patent Application Publication
(10) Pub. No.: US 2004/0157385 A1
(43) Pub. Date: Aug. 12, 2004

(54) Method for manufacturing a semiconductor device by using a dry etching technique

(75) Inventor: Nobuyuki Ikezawa, Kanagawa (JP)

Correspondence Address: FOLEY AND LARDNER, SUITE 500, 3000 K STREET NW, WASHINGTON, DC, 20007, US

(73) Assignee: NEC Electronics Corporation

(21) Appl. No.: 10/771,470

(22) Filed: Feb. 5, 2004

(30) Foreign Application Priority Data
Feb. 10, 2003 (JP) 2003-032916
Oct. 28, 2003 (JP) 2003-367285

(51) Int. Cl. H01L 21/336; H01L 21/8234; H01L 21/3205; H01L 21/4763; H01L 21/44

(52) U.S. Cl. 438/197; 438/585; 438/666

(57) ABSTRACT

A method for dry etching a polysilicon film to form gate electrodes in a CMOS LSI includes the steps of etching a first portion of the polysilicon film having a higher impurity concentration by using CF-based etching gas, such as CF₄, CHF₃ and CH₂O₂, etching a second portion of the polysilicon film having a lower impurity concentration by using etching gas such as Cl₂/O₂, HBr/O₂, Cl₂/HBr/O₂ and Cl₂/HBr/CF₄/O₂, and etching residues generated in the above etching steps. The CF-based etching gas allows the polysilicon film doped with n-type and p-type impurities to be etched at a uniform etch rate.

### BACKGROUND OF THE INVENTION

(a) Field of the Invention

The present invention relates to a method for manufacturing a semiconductor device by using a dry etching technique and, more particularly, to a method suited to forming gate electrodes in a CMOS LSI.

(b) Description of the Related Art

In a CMOS LSI, impurity ions are generally introduced into gate electrodes of MOSFETs by using an ion-implantation process such that phosphorous (P) or arsenic (As) ions are introduced into n-type gate electrodes formed in an nMOS area and boron (B) or boron difluoride (BF₂) ions are introduced into p-type gate electrodes formed in a pMOS area.

In a conventional technique for manufacturing a CMOS LSI, a polysilicon film is first deposited on a gate oxide film and configured to form gate electrodes by using a dry etching process, followed by implantation of phosphorous or arsenic ions into the n-type gate electrodes and boron or boron difluoride into the p-type electrodes during the ion-implantation step for configuring source-drain regions.

However, along with the recent development of finer device structure and higher performance of the CMOS LSI, both the formation of a shallower junction structure and prevention of generation of depleted layer within the gate electrode should be achieved independently of each other. For obtaining optimum conditions for each of ion-implantation of source-drain regions and ion-implantation of gate electrodes, implantation of phosphorous or arsenic ions into n-type source-drain regions and boron or boron difluoride ions into p-type source-drain regions should be performed before configuring the gate electrodes.

FIGS. 8A and 8B show a process described in Patent Publication JP-A-11-17024, wherein impurity ions are implanted into a gate electrode layer before configuring the gate electrode layer into respective gate electrodes.

In FIG. 8A, a polysilicon film 14 is formed on a silicon substrate 13 in the entire area with an intervention of a gate insulation film 12 therebetween, followed by implanting arsenic (As) ions into the polysilicon film 14 in the nMOS area 16 and implanting boron difluoride (BF₂) ions into the polysilicon film 14 in the pMOS area 17. A photoresist mask pattern 15 having a gate electrode pattern is then formed, covering portions 14a of the polysilicon film 14 to be left in the device and exposing other portions 14b to be etched. The other portions 14b are implanted with arsenic ions and then boron difluoride ions to obtain a substantially uniform impurity concentration in the exposed portions 14b over the nMOS area 16 and pMOS area 17. The exposed portions 14b of the polysilicon film 14 are then etched selectively from the covered portions 14a to form gate electrodes by using the photoresist mask pattern 15 as an etching mask, as shown in FIG. 8B. In this technique, the exposed portions 14b having the substantially uniform impurity concentration exhibits a uniform etch rate, thereby preventing generation of etching residues or a damage in the gate oxide film 12.

A dry etching process is generally used for etching the polysilicon film 14, including a breakthrough stage for removing a native oxide film formed on the surface of the polysilicon film 14, a main etching stage for configuring the polysilicon film 14 into gate electrodes, and an over-etching stage for removing the residues of the etched polysilicon while suppressing a damage on the silicon surface.

The breakthrough stage uses chlorine gas and CF₄ gas, the main etching stage uses a mixture of chlorine, hydrogen bromide and oxygen, and the over-etching stage uses a mixture of hydrogen bromide and oxygen. If the polysilicon film is not implanted with impurity ions, these stages in combination will achieve an excellent etching performance with an accurate shape of the resultant gate electrodes and without a damage on the substrate.

However, since the gate electrode layer 14 is implanted with impurity ions in the above publication, there arises a difference in the etch rate of the gate electrode layer 14 between the nMOS area 16 and the pMOS area 17. This difference may cause an under-etching of the p-type gate electrodes in the pMOS area 17 if the etching condition is optimized for the n-type gate electrodes, and may cause an over-etching of the n-type electrodes in the nMOS area 16, such as shown in FIG. 7, if the etching condition is optimized for the p-type gate electrodes.

The difference in the etching rate results from the fact that the gate electrode layer 14 in the nMOS area 16 implanted with the n-type impurity ions has a higher etch rate and a higher reactivity with the etching gas than the gate electrode layer 14 in the pMOS area 17 implanted with the p-type impurity ions. More specifically, the polysilicon film 14 doped with phosphorous or arsenic ions (n-type impurities) has a higher electron density, resulting in a higher etching rate and a higher reactivity, whereas the polysilicon film 14 doped with boron ions (p-type impurities) has a lower electron density (higher positive-hole density), resulting in a lower etching rate and a lower reactivity. Thus, the difference arises in the shape and dimensions of the gate electrodes between the nMOS area and the pMOS area.

### SUMMARY OF THE INVENTION

It is an object of the present invention to provide a method for manufacturing a semiconductor device, which is capable of reducing the difference in the shape and dimensions of the gate electrodes between the pMOS area and the nMOS area, for example, of the semiconductor device.

The present invention provides a method for manufacturing a semiconductor device including the steps of: forming a polysilicon film including a first portion doped with impurities at a first impurity concentration and a second portion doped with impurities at a second impurity concentration which is lower than the first impurity concentration; and selectively etching the first portion of the polysilicon film by using a first etching condition and the second portion of the polysilicon film by using a second etching condition to thereby form gate electrodes from the first and second portions of the polysilicon film, the first etching condition generating a less amount of side etching compared to the second etching condition.

In accordance with the method of the present invention, the first etching condition provides a uniform etch rate for the first portion having a higher impurity concentration irrespective of the conductivity-type of the impurities due to the less amount of the side etching, and the second etching condition provides a sufficient etch selectivity of the polysilicon film for the second portion having a lower impurity concentration due to a larger amount of side etching. Thus, the selective etching step of the present invention provides a uniform shape and uniform dimensions for the gate electrodes irrespective of the conductivity-type of the impurities doped in the polysilicon film.

The above and other objects, features and advantages of the present invention will be more apparent from the following description, referring to the accompanying drawings.

### BRIEF DESCRIPTION OF THE DRAWINGS

FIGS. 1A to 1E are sectional views of a semiconductor device during consecutive steps in a fabrication process according to an embodiment of the present invention.

FIG. 2 shows an impurity concentration profile of p-type impurities in the gate electrode layer formed in the process of the embodiment.

FIG. 3 is an explanatory sectional view showing the mechanism for suppression of side etching in the embodiment.

FIG. 4 is a sectional view of the gate electrodes in the semiconductor device manufactured by the process of the embodiment, obtained by tracing the image of a scanning electron microscope.

FIG. 5 is a graph showing the cumulative probability of the difference in the gate width between the nMOS area and the pMOS area in the method of the embodiment.

FIG. 6 is an explanatory sectional view showing the mechanism of generation of the side etching in the conventional technique.

FIG. 7 is a sectional view of the gate electrodes in a conventional semiconductor device.

FIGS. 8A and B are sectional views of a conventional semiconductor device during consecutive steps of fabrication thereof.

### PREFERRED EMBODIMENT OF THE INVENTION

Now, the present invention is more specifically described with reference to accompanying drawings.

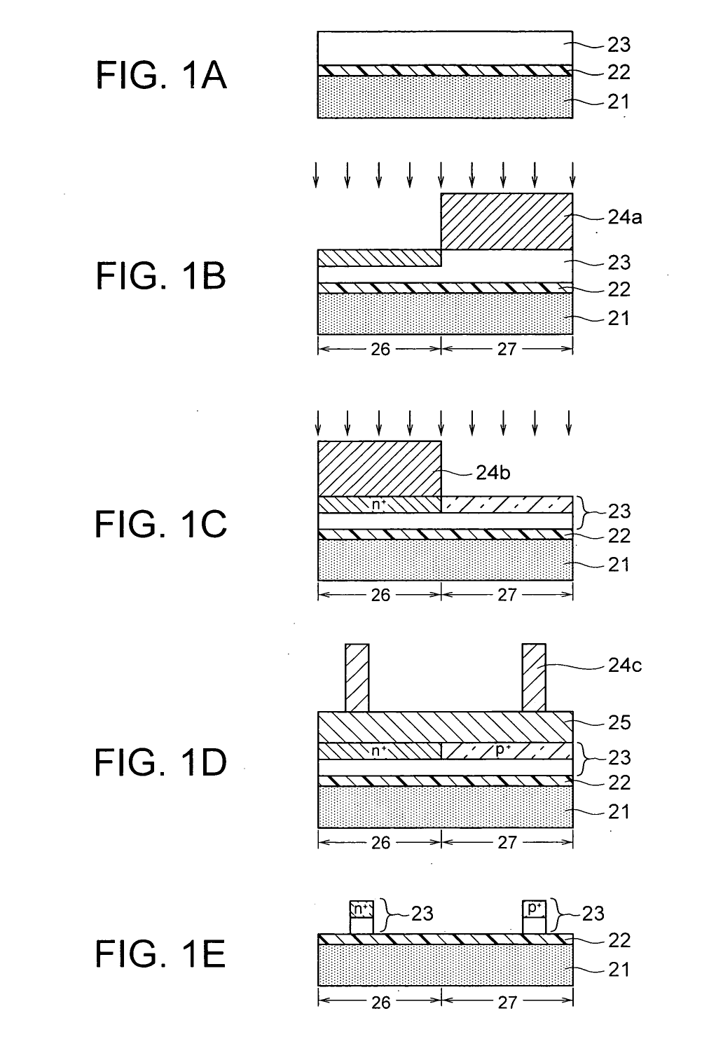

Referring to FIG. 1A, a gate electrode layer 23 is formed on a silicon substrate 21 with an intervention of a gate oxide film 22, the gate oxide film 22 being formed by a thermal oxidation process of the surface of the silicon substrate 21, for example. The gate electrode layer 23 is a CVD polysilicon film having a thickness of 50 to 200 nm, for example.

A photoresist mask 24a covering the pMOS area 27 and exposing the nMOS area 26 is formed on the polysilicon film 23, as shown in FIG. 1B. Impurity ions, such as phosphorous or arsenic ions, are then implanted to the polysilicon film 23 in the nMOS area 26 by using the photoresist mask 24a as a mask for implanting the impurity ions at an acceleration energy of 1 to 20 keV and a dosage of 5E14 to 1E16 atoms/cm². Thereafter, the photoresist mask 24a is removed.

Another photoresist mask 24b covering the nMOS area 26 and exposing the pMOS area 27 is then formed on the polysilicon film 23, as shown in FIG. 1C. Impurity ions, such as boron or boron difluoride ions, are then implanted to the polysilicon film 23 in the pMOS area 27 by using the another photoresist mask 24b as a mask for implanting the impurity ions at an acceleration energy of 1 to 10 keV and a dosage of 5E14 to 1E16 atoms/cm². The another photoresist mask 24b is then removed. It is to be noted that the order of the ion-implantation of the nMOS area 26 and the pMOS area 27 may be reversed.

Subsequently, an anti-reflection film 25 is formed on the polysilicon film 23 implanted with the n-type and p-type impurities, thereby reducing the reflected light from the surface of the polysilicon film 23. The anti-reflection film 25 may be made of inorganic material such as SiN, SiON or TiN or an organic resin. Another photoresist mask 24c having a gate electrode pattern is then formed on the anti-reflection film 25 by using a photolithographic and etching technique, as shown in FIG. 1D.

The photolithographic and etching technique uses KrF laser having a wavelength of 248 nm or ArF laser having a wavelength of 193 nm. The photolithographic and etching technique may use an electron-beam lithographic and etching technique instead. The photolithographic and etching process using the KrF or ArF laser should use the anti-reflection film 25 from the view point of reduction of the reflected light.

In the example, since the anti-reflection film 25 is made of an organic resin, an ICP-type dry etching system is used for etching the anti-reflection film 25 and the polysilicon film 23 while using a 13.56-MHz source power and a 13.56-MHz bias power.

The etching for the organic anti-reflection film 25 and the etching for the polysilicon film 23 are consecutively conducted in a single etching chamber. The organic anti-reflection film 25 may be etched by using a mixture of gases such as chlorine/oxygen, hydrogen bromide/oxygen or carbon tetra-fluoride/oxygen.

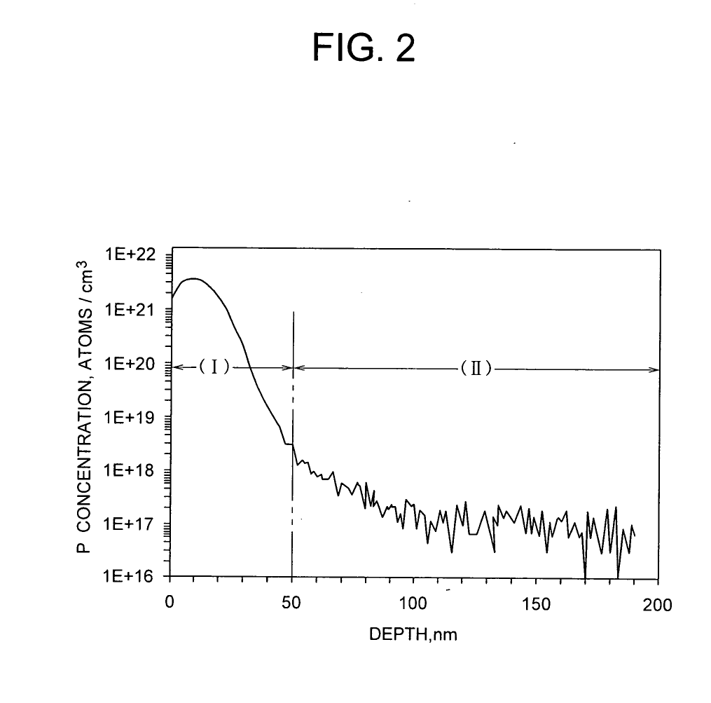

FIG. 2 shows the impurity concentration profile of the polysilicon film 23 in the exemplified pMOS area and the depths for the etching during the selective etching process shown in FIG. 1E. As understood from FIG. 2, the impurity concentration of the polysilicon film 23 in each of the nMOS area and the pMOS area has a higher value in the range from the top surface to the depth of 50 nm, and a lower value below the depth of 50 nm.

The polysilicon film 23 is etched by using the photoresist mask 24c and three stages of the etching. The three stages includes a first stage for etching a first portion (I) of the polysilicon film 23 having a higher impurity concentration roughly above 1E18 atoms/cm³, or having an impurity concentration from the maximum impurity concentration to the inflexion point, and a second stage for etching a second portion (II) of the polysilicon film 23 having a lower impurity concentration roughly from the inflexion point to the bottom of the polysilicon film 23, and a third stage for removing the residues generated in the above etching stages. The inflexion point in the embodiment may be referred to as an impurity concentration which is three digits lower than the maximum impurity concentration, and may be a depth of 50 nm, for example.

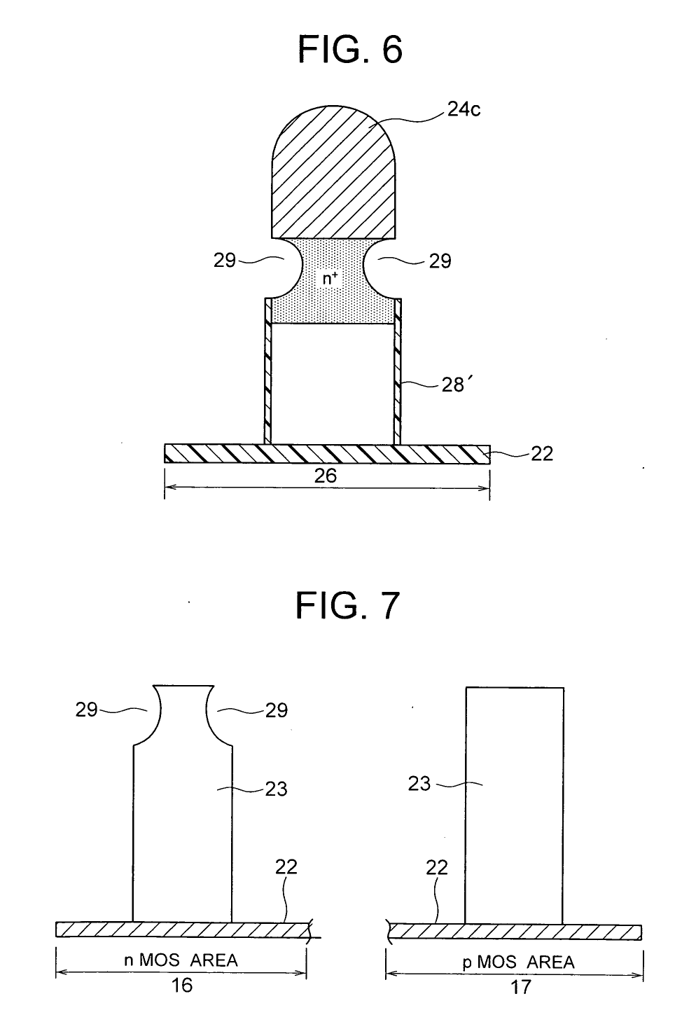

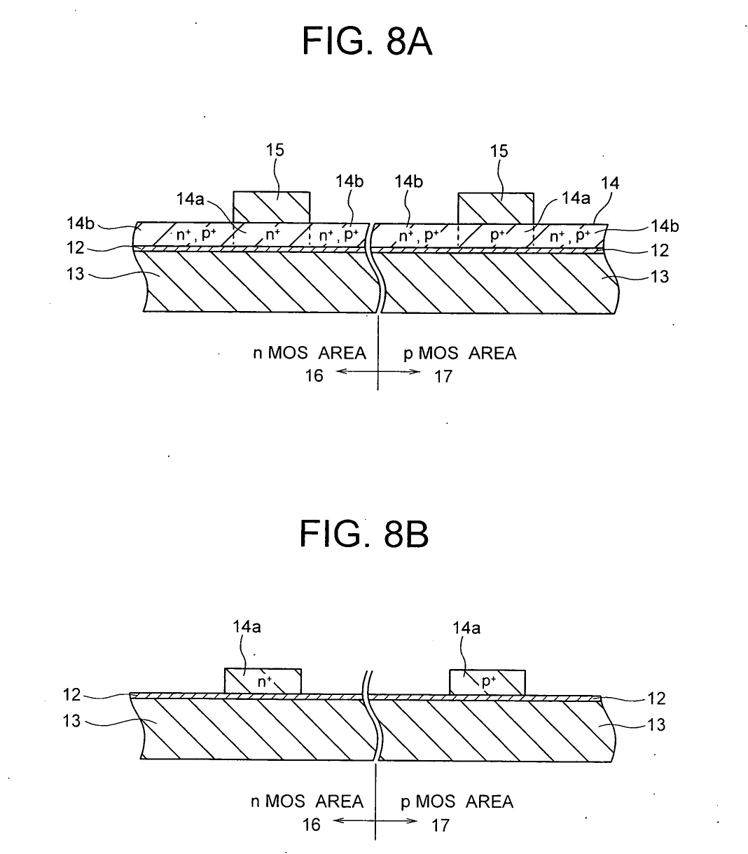

It is to be noted that the portion (I) of the polysilicon film 23 doped with a higher impurity concentration (especially in the nMOS area 26) is often observed to have a higher side etching 29, such as shown in FIG. 6, if a mixture of chlorine/oxygen, hydrogen bromide/oxygen, or chlorine/hydrogen bromide/oxygen generally used for this purpose is used as an etching gas. In general, the anisotropic shape is generated during the etching by the competition between the etching process and the deposition process both occurring during the same etching step. These general mixtures of gas provide side wall protective film 28′ (FIG. 6) of SiClₓ or SiBrₓ as the reaction products of the etching gas and the silicon on the side wall of the gate electrode, and cause a higher etch rate at the initial stage of the etching step compared to the deposition rate, whereby the side etching 29 is observed on the gate electrode. In FIG. 6, numeral 24c denotes a photoresist mask formed on the polysilicon film.

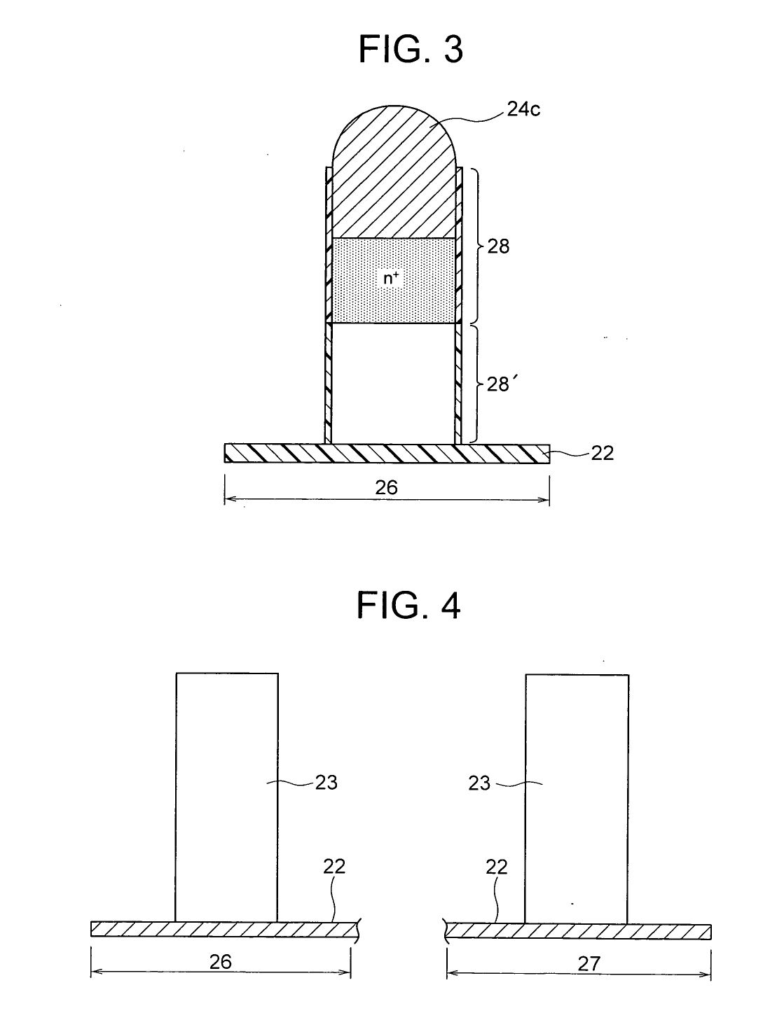

Since the etching gas in the present embodiment includes CF-based gas, such as CF₄, CHF₃ and CH₂F₂, as a main component thereof, the reaction product CFₓ provided from the CF-based gas acts as a side-wall protective film 28, as shown in FIG. 3. This side-wall protective film 28 advantageously protects the polysilicon gate structure against the side etching during the first and second stages of the etching step, whereby a suitable anisotropic etching can be achieved even in the nMOS area 26 as well as the pMOS area 27. In FIG. 3, numeral 28′ denotes a side-wall SiCₓ or SiBrₓ film formed in the next stage of the etching step.

Preferable etching conditions at the first stage of the etching step in the embodiment may be:

### EXAMPLE 1

an ambient pressure of 10 mTorr, a source power of 400 watts, a bias power of 100 watts, CF₄ for the etching gas at a flow rate of 100 sccm (standard cubic centimeters per minutes), and an etching amount of about 50 nm;

### EXAMPLE 2

an ambient pressure of 10 mTorr, a source power of 400 watts, a bias power of 100 watts, CF₄/He for the etching gas at a flow rate of 100 sccm/50 sccm, and an etching amount of about 50 nm;

### EXAMPLE 3

an ambient pressure of 10 mTorr, a source power of 400 watts, a bias power of 100 watts, CF₄/He for the etching gas at a flow rate of 100 sccm/100 sccm, and an etching amount of about 50 nm;

### EXAMPLE 4

an ambient pressure of 10 mTorr, a source power of 400 watts, a bias power of 100 watts, CF₄/He for the etching gas at a flow rate of 50 sccm/100 sccm, and an etching amount of about 50 nm;

### EXAMPLE 5

an ambient pressure of 10 mTorr, a source power of 400 watts, a bias power of 100 watts, CF₄/Cl₂ for the etching gas at a flow rate of 100 sccm/10 sccm, and an etching amount of about 50 nm;

### EXAMPLE 6

an ambient pressure of 10 mTorr, a source power of 400 watts, a bias power of 100 watts, CF₄/HBr for the etching gas at a flow rate of 100 sccm/10 sccm, and an etching amount of about 50 nm; and

### EXAMPLE 7

an ambient pressure of 10 mTorr, a source power of 400 watts, a bias power of 100 watts, CF₄/O₂ for the etching gas at a flow rate of 100 sccm/4 sccm, and an etching amount of about 50 nm.

The above examples include typical etching gas, and He in the above etching gas may be replaced by Ar, for example. In addition, CF₄ may be replaced by CHF₃ or CH₂F₂. In the above examples, the parameters other than the etching gas are fixed; however, the ambient pressure may be in the range of 3 to 20 mTorr, the source power may be in the range of 200 to 600 watts, and the bias power may be in the range of 20 to 150 watts, instead of the above fixed parameters.

The present invention is based on the principle that the CF-based gas allows the polysilicon film doped with n-type and p-type impurities to be etched at a uniform etch rate substantially without the side etching for the portion of the polysilicon film doped with a higher impurity concentration.

After using one of the above conditions at the first stage of the etching stage for etching the portion (I) of the polysilicon film 23 doped with a higher impurity concentration, the above condition is switched to another condition for etching the remaining portion (II) of the polysilicon film 23 doped with a lower impurity concentration. The reasons for switching the etching condition are that the etching stage using the CF-based gas has a lower etch selectivity of polysilicon against the photoresist mask (etch selectivity of polysilicon to photoresist is around 1:0.7 to 2, for example), and that the etching stage using the CF-based gas has also a lower etch selectivity of polysilicon against the silicon oxide film and thus may cause a damage on the gate insulating film. After switching to the next etching condition, etching gas, such as Cl₂/O₂, HBr/O₂, Cl₂/HBr/O₂, Cl₂/HBr/CF₄ or Cl₂/HBr/CF₄/O₂ generally known is used. The etching step is performed until or just before the substrate surface is exposed, where the remaining polysilicon film has a thickness of around or below 30 nm.

The remaining thin portion of the polysilicon film 23 is then etched using HBr/O₂-based etching gas having a high etch selectivity (10:1 or more) of polysilicon against the silicon oxide film until the gate oxide film 22 is exposed. After the gate oxide film 22 is exposed, the etching gas is again switched to HBr/O₂-based gas having a higher etch selectivity (100:1 or more) of polysilicon against the silicon oxide film. In this case, the ambient pressure is also raised together with the switching of the etching gas.

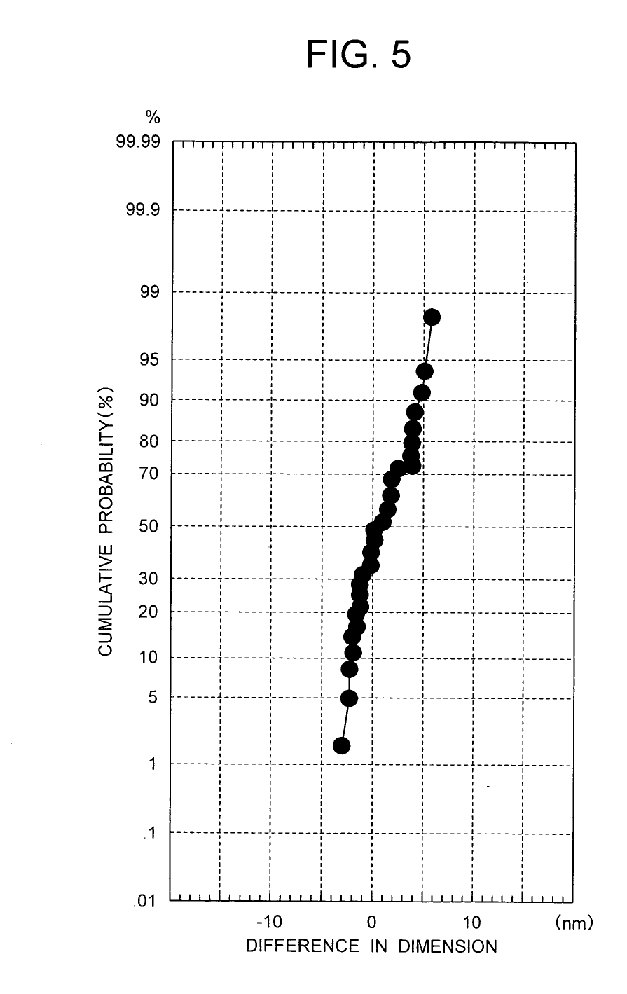

By using the above four etching stages having different etching conditions, a smaller difference in the shape of the gate electrodes 23 can be obtained between the nMOS area 26 and the pMOS area 27, as depicted in FIG. 4. In addition, a smaller difference in the gate width of the final product between the nMOS area 26 and the pMOS area 27 can be also obtained, as depicted in FIG. 5.

FIG. 5 shows the percent cumulative probability of the difference in the gate width of the final product between the nMOS area 26 and the pMOS area 27 in the case using the etching conditions as described above. It is to be noted that the average of the differences in the gate width between the nMOS area 26 and the pMOS area 27 of the final product was as low as 0.95 nm for a design gate width, such as 100 nm.

In the above embodiment, the gate electrodes are configured from a polysilicon film; however, the gate electrodes may have a two- or more-layer structure including a polysilicon film and a polysilicon germanium film, for example. In addition, the polysilicon film may be replaced by an amorphous silicon film or silicon germanium film.

The ICP-type dry etching system may be replaced by ECR-type, two-frequency RIE-type, or magnetron RIE-type dry etching system while using the CF-based etching gas. It is preferable that the first etching stage use an etching gas including CF-based gas at a volume ratio of 75% or more with respect to the total etching gas.

Since the above embodiment is described only for an example, the present invention is not limited to the above embodiment and various modifications or alterations can be easily made therefrom by those skilled in the art without departing from the scope of the present invention.

What is claimed is:

1. A method for manufacturing a semiconductor device comprising the steps of:
forming a polysilicon film including a first portion doped with impurities at a first impurity concentration and a second portion doped with impurities at a second impurity concentration which is lower than said first impurity concentration; and
selectively etching said first portion of said polysilicon film by using a first etching condition and said second portion of said polysilicon film by using a second etching condition to thereby form gate electrodes from said first and second portions of said polysilicon film, said first etching condition generating a less amount of side etching compared to said second etching condition.

2. The method according to claim 1, wherein said polysilicon film includes said first and second portions in each of an nMOS area and a pMOS area, and is doped with n-type impurity ions in said nMOS area and doped with p-type impurity ions in said pMOS area.

3. The method according to claim 1, further comprising the step of forming an anti-reflection film on said polysilicon film before said selectively etching step.

4. The method according to claim 3, wherein said anti-reflection film includes an organic resin.

5. The method according to claim 1, wherein said first etching condition uses CF-based etching gas.

6. The method according to claim 5, wherein said CF-based etching gas includes CF₄, CHF₃ and/or CH₂F₂.

7. The method according to claim 5, wherein said first etching condition includes an ambient pressure of 3 to 20 mTorr, a source power of 200 to 600 watts, a bias power of 20 to 150 watts, and a volume ratio of said CF-based gas to total gas at 75% or more.

8. The method according to claim 5, wherein said second etching condition uses Cl₂/O₂, HBr/O₂, Cl₂/HBr/O₂, Cl₂HBr/CF₄, or Cl₂/HBr/CF₄/O₂.
